(19) United States
(12) Patent Application Publication
(10) Pub. No.: US 2006/0102320 A1
(43) Pub. Date: May 18, 2006

(54) Heat sink

(75) Inventors: Chi-Chang Lin, LuZhou City (TW); Chih-Yuan Cheng, Baqiao City (TW); Heng-Tsung Wang, Taipei City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: ASUSTek Computer Inc.

(21) Appl. No.: 11/243,057

(22) Filed: Oct. 4, 2005

(30) Foreign Application Priority Data
Nov. 12, 2004 (TW) 93134630

(51) Int. Cl. H05K 7/20

(52) U.S. Cl. 165/80.3; 361/704

(57) ABSTRACT

A heat sink is disclosed. A plurality of fins is radially and uniformly connected to a central base. Each fin comprises a plurality of protrusions. The protrusions are uniformly formed on each fin around the circumference of the central base.

### BACKGROUND

The invention relates to a heat sink, and in particular to a heat sink enhancing heat transfer.

A microelectronic device, such as an integrated circuit device, a microprocessor, or a computer-related device, can have more applications with increasing performance. The increased performance results in increased heat from the microelectronic device. Moreover, the microelectronic device is generally combined with a heat sink. Heat generated by the microelectronic device can be transferred to the environment via the heat sink, thereby reducing the temperature of the microelectronic device. Nevertheless, the capability of heat dissipation of the heat sink must be increased when the heat generated from the microelectronic device is increased.

The U.S. Pat. No. 6,633,484 discloses the conventional radial-type heat sinks used to increase the heat dissipation. The conventional radial-type heat sinks increase the area for heat transfer by means of radial-type fins. When heat generated by the microelectronic device increases and the surface areas of the conventional heat sinks, on which the microelectronic device is disposed, are fixed, the radial-type fins of the conventional heat sinks must be correspondingly increased to increase the areas for heat transferring. Conventional heat sinks are generally formed or manufactured by extrusion of aluminum. The extrusion process, however, is limited to a predetermined ratio of length to width. The increased radial-type fins may cause extrusion failure, damage to extrusion molds, and reduced lifespan of the extrusion molds.

Hence, a heat sink capable of increasing the area for heat transfer without increasing the extrusion ratio of length to width is provided for reducing the temperature of the microelectronic device connected thereto.

### SUMMARY

Accordingly, an exemplary embodiment provides a heat sink comprising a central base and a plurality of fins. The fins are radially and uniformly connected to the central base. Each fin comprises a plurality of protrusions. The protrusions are uniformly formed on each fin around the circumference of the central base.

The central base comprises a hollow cylinder. The fins are radially and uniformly connected to the outer circumference of the hollow cylinder.

The central base comprises a cylinder. The fins are radially and uniformly connected to the circumference of the cylinder.

The central base further comprises an outer annular portion and a solid inner portion. The solid inner portion is disposed in the outer annular portion, and the fins are radially and uniformly connected to the outer circumference of the outer annular portion.

The height of the solid inner portion is equal to or smaller than that of the outer annular portion.

The solid inner portion comprises copper, copper-based alloy, or porous copper.

The outer annular portion, fins, and protrusions are integrally formed.

The fins are provided with a same curved profile.

The fins are provided with a same curvature.

The central base, fins, and protrusions are integrally formed by extrusion.

The heat sink further comprises a base connected to the central base. The heat sink is connected to a microelectronic device by means of the base.

The heat sink further comprises at least one fixing member extended from the base to fix the heat sink on the microelectronic device.

### DESCRIPTION OF THE DRAWINGS

The invention can be more fully understood by reading the subsequent detailed description and examples with references made to the accompanying drawings, wherein:

FIG. 1 is a schematic partial top view of the heat sink of an embodiment of the invention;

FIG. 2 is a schematic front view of FIG. 1;

FIG. 3 is a schematic enlarged view of FIG. 1; and

FIG. 4 is a schematic partial top view of the heat sink of another embodiment of the invention.

### DETAILED DESCRIPTION

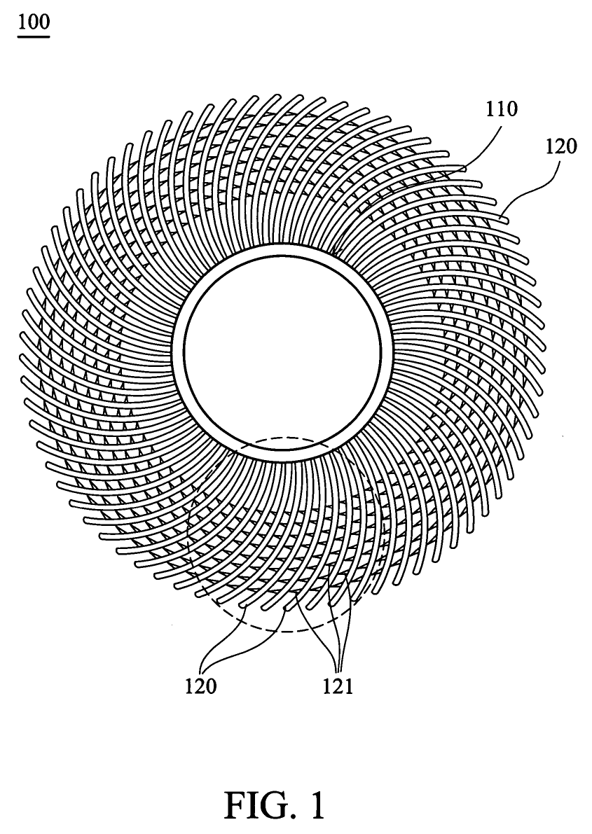

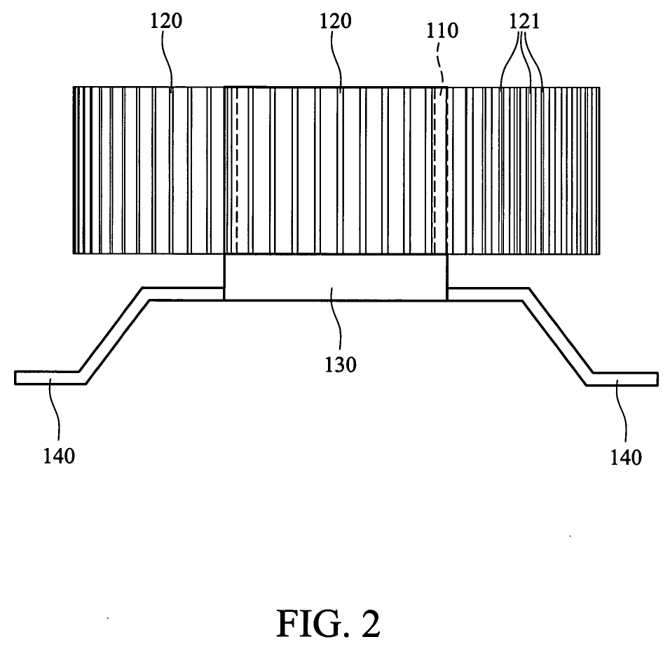

Referring to FIG. 1 and FIG. 2, the heat sink 100 comprises a central base 110 and a plurality of fins 120.

The central base 110 may be a hollow cylinder or a cylinder. In an embodiment, the central base 110 is a hollow cylinder. As shown in FIG. 1, the fins 120 are provided with a substantially same curvature (or curved profile) and are radially and uniformly connected to the outer circumference of the central base 110 (hollow cylinder). Accordingly, the heat sink 100 is thus provided with a helically radial profile.

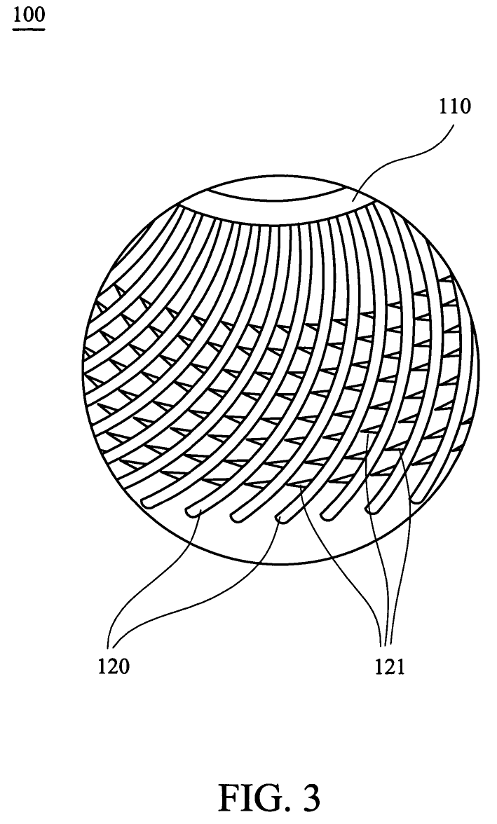

Specifically, as shown in FIG. 1 and FIG. 3, each fin 120 comprises a plurality of protrusions 121, and the protrusions 121 are uniformly formed on each fin 120 around the circumference of the central base 110. Namely, the protrusions 121 are uniformly formed around the circumference of each fin 120 in the same direction. The protrusions 121 are preferably triangular.

As shown in FIG. 2, the heat sink 100 further comprises a base 130 and a plurality of fixing members 140. The base 130 is connected to the central base 110. The fixing members 140 are connected to the base 130 and extended outward therefrom. When the heat sink 100 is disposed on the surface of a microelectronic device, such as an integrated circuit device, a microprocessor, or a computer-related device, the base 130 is directly connected to the microelectronic device and the fixing members 140 can fix the heat sink 100 on a main board containing the microelectronic device.

Accordingly, because the protrusions 121 are uniformly formed on each fin 120 around the circumference of the central base 110, the heat sink 100 can provide a larger area for heat transfer than conventional heat sinks. Thus, when connected to the microelectronic device, the heat sink 100 can effectively transfer or remove heat generated by the microelectronic device, effectively reducing the temperature thereof.

Moreover, the heat sink 100 has the following advantage. The heat sink 100 can overcome manufacturing difficulties. Namely, the central base 110, fins 120, and protrusions 121 can be integrally formed by extrusion when the extrusion ratio of length to width is fixed or not greatly increased. Thus, manufacture of the heat sink 100 can be successful and damage to the extrusion molds can be prevented, prolonging the lifespan of the extrusion molds.

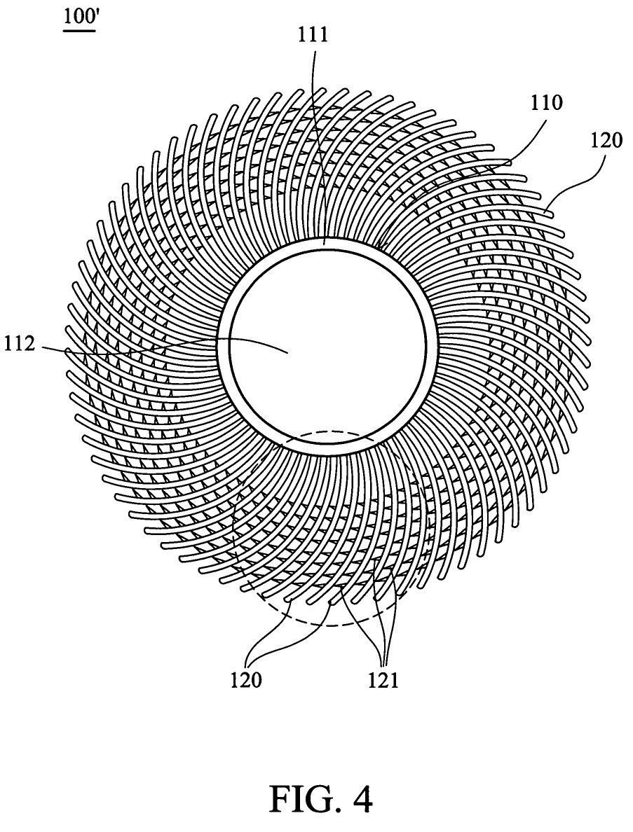

As shown in FIG. 4, the central base 110 of another heat sink 100′ comprises an outer annular portion 111 and a solid inner portion 112. The solid inner portion 112 is disposed in the outer annular portion 111, and the fins 120 are radially and uniformly connected to the outer circumference of the outer annular portion 111. Specifically, the height of the solid inner portion 112 can be equal to or less than that of the outer annular portion 111. The solid inner portion 112 may comprise copper, copper-based alloy, or porous copper.

Similarly, the outer annular portion 111, fins 120, and protrusions 121 can be integrally formed by extrusion when the extrusion ratio of length to width is fixed or not greatly increased. Moreover, the protrusions 121 are preferably triangular. Thus, manufacture of the heat sink 100′ can be successful and damage to the extrusion molds can be prevented, prolonging the lifespan of the extrusion molds.

Accordingly, when the heat sink 100′ is connected to a microelectronic device, the solid inner portion 112 can enhance heat conduction between the heat sink 100′ and the microelectronic device. Thus, the heat generated by the microelectronic device can be more rapidly dissipated.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A heat sink, comprising:
a central base; and
a plurality of fins radially and uniformly connected to the central base, wherein each fin comprises a plurality of protrusions, and the protrusions are uniformly formed on each fin around the circumference of the central base.

2. The heat sink as claimed in claim 1, wherein the central base comprises a hollow cylinder, and the fins are radially and uniformly connected to the outer circumference of the hollow cylinder.

3. The heat sink as claimed in claim 1, wherein the central base comprises a cylinder, and the fins are radially and uniformly connected to the circumference of the cylinder.

4. The heat sink as claimed in claim 1, wherein the central base further comprises an outer annular portion and a solid inner portion, the solid inner portion is disposed in the outer annular portion, and the fins are radially and uniformly connected to the outer circumference of the outer annular portion.

5. The heat sink as claimed in claim 4, wherein the height of the inner solid portion is equal to or less than that of the outer annular portion.

6. The heat sink as claimed in claim 4, wherein the solid inner portion comprises copper, copper-based alloy, or porous copper.

7. The heat sink as claimed in claim 4, wherein the outer annular portion, fins, and protrusions are integrally formed.

8. The heat sink as claimed in claim 1, wherein the fins are provided with a same curved profile.

9. The heat sink as claimed in claim 8, wherein the fins are provided with a same curvature.

10. The heat sink as claimed in claim 1, wherein the central base, fins, and protrusions are integrally formed.

11. The heat sink as claimed in claim 1, wherein the central base, fins, and protrusions are integrally formed by extrusion.

12. The heat sink as claimed in claim 1, further comprising a base connected to the central base, wherein the heat sink is connected to a microelectronic device by means of the base.

13. The heat sink as claimed in claim 12, further comprising at least one fixing member extended from the base to fix the heat sink.
